(19) United States
(12) Patent Application Publication
(10) Pub. No.: US 2007/0052004 A1
(43) Pub. Date: Mar. 8, 2007

(54) Method of manufacturing nano crystals and application of the same

(75) Inventors: Chih-Wei Chao, Taipei City (TW); Mao-Yi Chang, Taoyuan City (TW); I-Chang Tsao, Hsinchu City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/320,061

(22) Filed: Dec. 28, 2005

(30) Foreign Application Priority Data
Sep. 5, 2005 (TW) 94130426

(51) Int. Cl. H01L 29/788

(52) U.S. Cl. 257/315

(57) ABSTRACT

A method of manufacturing nano crystals disclosed herein is applicable to the fabrications of memory device and solar cell. The method of manufacturing nano crystals at least comprises steps of: providing a substrate with a thin film formed thereon, and transforming the thin film into the nano crystals by laser annealing, wherein a thickness of the thin film is equal to or less than about 50 Å, and a wavelength of the laser selected for laser annealing is equal to or less than about 500 nm.

This application claims the benefit of Taiwan application Serial No. 094130426, filed Sep. 5, 2005, the subject matter of which is incorporated herein by reference.

### BACKGROUND OF THE INVENTION

1. Field of the Invention

The invention relates in general to a method of manufacturing nano crystals and application of the same, and more particularly to the method of manufacturing nano crystals at a low temperature and application of the same.

2. Description of the Related Art

The crystals with nano sizes possess various advantages, for example, in the application of the memory device for being the quantum well to trap the electrons. Also, the nano crystals are featured with properties of light absorption (i.e. good absorbency index), and become one of the excellent light-absorption materials. Taking the silicon crystals as an example, the silicon crystals having regular size are able to store 30% of light energy, and the silicon crystals having nano size are able to store 50%-60% of light energy.

Conventionally, the nano crystals can be formed by two methods. The first conventional method is to form the nano crystals on the substrate by chemical vapor deposition, and the processing temperature is about 650° C. at least. The second conventional method is to introduce the semiconductor such as silicon (Si) or germanium (Ge) into the silicon oxide (SiO₂) film by ion implantation, and then the nano Si or Ge crystals are formed in the SiO₂ film by thermal-annealing at a temperature of about 800° C. at least. Both conventional methods require high temperature procedures, which are not compatible with the process of making low-temperature poly-silicon thin film transistor (LTPS TFT).

### SUMMARY OF THE INVENTION

It is therefore an object of the present invention to provide a method of manufacturing nano crystals and application of the same. The method of the present invention utilizes a thin film and low-temperature laser annealing to produce the nano crystals; thus, it is particularly compatible with the process of making low-temperature poly-silicon thin film transistor (LTPS TFT).

The present invention achieves the objects by providing a method of manufacturing nano crystals, comprising steps of:

providing a substrate;

forming a thin film on the substrate, and a thickness of the thin film equal to or less than about 50 Å; and

subjecting the thin film under a laser annealing to transform the thin film into a plurality of nano crystals, and a wavelength of the laser selected for laser annealing equal to or less than about 500 nm.

The present invention achieves the objects by providing a semiconductor structure having nano crystals. The structure comprises a substrate, and a plurality of nano crystals formed on the substrate at a low crystallizing temperature. Also, a particle size average of the nano crystals is less than about 10 nm.

Other objects, features, and advantages of the present invention will become apparent from the following detailed description of the preferred but non-limiting embodiment. The following description is made with reference to the accompanying drawings.

### BRIEF DESCRIPTION OF THE DRAWINGS

FIG. 1A and FIG. 1B are cross-sectional views showing a method of manufacturing nano crystals according to the embodiment of the present invention.

FIG. 2 is TEM (transmission electron microscope) result of the nano crystals manufactured by the embodiment of the present invention.

FIG. 3A˜FIG. 3C are cross-sectional views showing a method of manufacturing the memory device having nano crystals according to the embodiment of the present invention.

FIG. 4 is a graph showing the electrical property of the memory device having nano crystals manufactured according to the method of the present invention.

FIG. 5A˜5D are cross-sectional views showing a method of manufacturing the solar cell having nano crystals according to the embodiment of the present invention.

### DETAILED DESCRIPTION OF THE INVENTION

In the present embodiment of the invention, a method of manufacturing nano crystals and application of the same are disclosed. It is noted that the embodiment disclosed herein is used for illustrating the present invention, but not for limiting the scope of the present invention. Additionally, the drawings used for illustrating the embodiment and applications of the present invention only show the major characteristic parts in order to avoid obscuring the present invention. Accordingly, the specification and the drawings are to be regard as an illustrative sense rather than a restrictive sense.

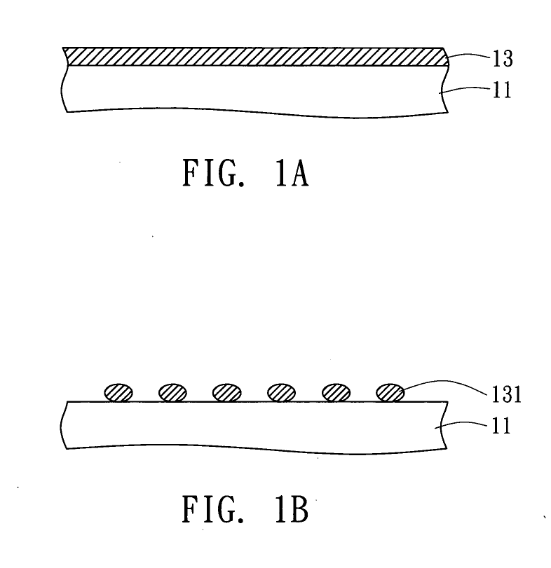

FIG. 1A and FIG. 1B are cross-sectional views showing a method of manufacturing nano crystals according to the embodiment of the present invention. First, a substrate 11 is provided. The substrate 11 is preferably made of the material with no capability of storing laser light energy, such as glass, plastics, silicon oxide and metals. Then, a thin film 13 is formed on the substrate 11 as shown in FIG. 1A, and a thickness of the thin film 13 is equal to or less than about 50 Å, and preferably about 15˜25 Å. Material for making the thin film 13 depends on the requirement of the practical application. Commonly, material of the thin film 13 includes silicon (Si), germanium (Ge) or SiGe.

Next, the thin film 13 is subjected under a laser annealing to transform the thin film 13 into the nano crystals 131. A wavelength of the laser selected for laser annealing is equal to or less than about 500 nm, and preferably in the range of 200 nm to 500 nm. Also, the particle size average of nano crystals 131 is about 10 nm or less.

Furthermore, an insulative layer (not shown) can be formed on the substrate 11 before deposition of the thin film 13. Examples of the insulative layer include silicon oxide, silicon nitride, and a combination thereof. However, formation of the insulative layer is not a necessary step of the method according to the present invention. Whether the insulative layer will be formed depends on the requirement of practical application.

It is noted that the laser annealing step can be performed at a low temperature, such as room temperature. In other words, the nano crystals 131 can be grown on the substrate 11 at room temperature by using the method described above. Thus, the method of the present invention is particularly suitable for manufacturing the nano crystals on the substrate incapable of withstanding thermal procedure. Accordingly, the method of the present invention is compatible with the process of making low-temperature poly-silicon thin film transistor (LTPS TFT).

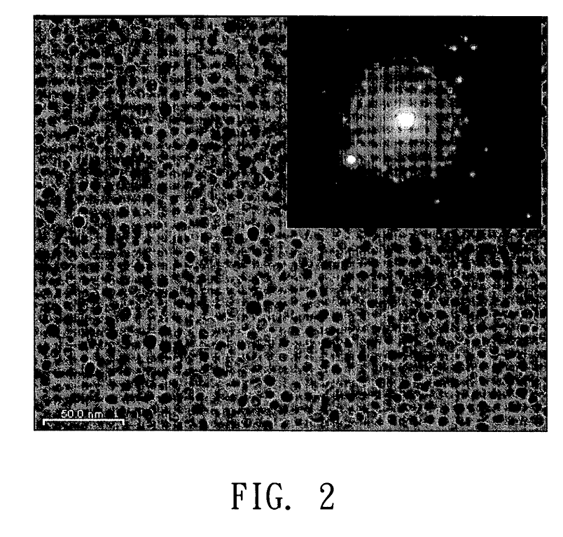

The nano crystals manufactured by the embodiment of the present invention are further observed by transmission electron microscope (TEM), and the result is presented in FIG. 2. The result clearly shows that those tiny particles are nano-sized and crystallized.

The nano crystals manufactured by the embodiment of the present invention possess several advantages, such as being the quantum wells and able to store higher light energy. Accordingly, two practical applications are disclosed herein for the advanced illustrations. It is, of course, understood that the present invention is applicable in many fields, and the memory device and solar cell just two of them.

Application 1: Memory Device

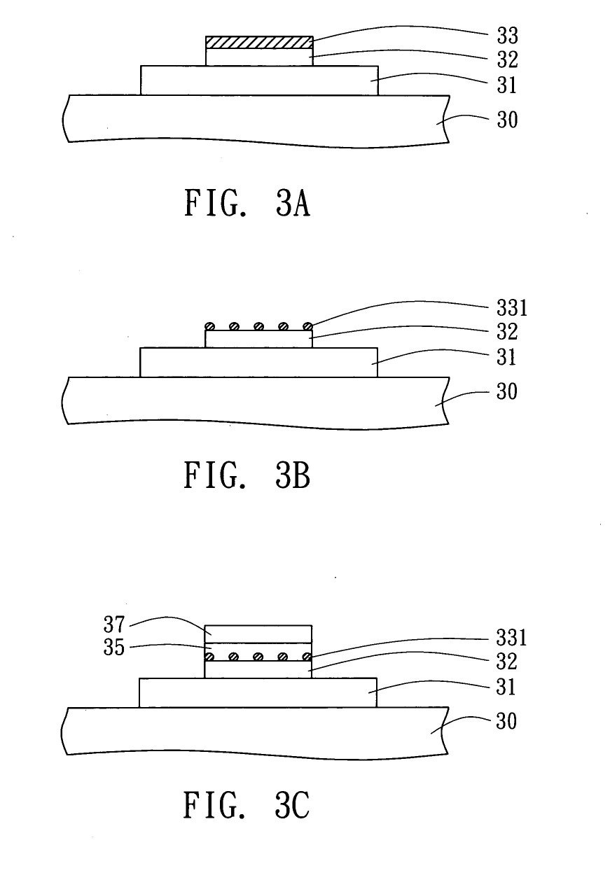

FIG. 3A˜FIG. 3C are cross-sectional views showing a method of manufacturing the memory device having nano crystals according to the embodiment of the present invention. First, a substrate 30 such as a transparent glass is provided. Then, a polysilicon layer 31 is formed on the substrate 30. Practically, an amorphous layer with a certain thickness is formed on the substrate 30 and then crystallized to form the polysilicon layer 31 by the known technique such as Excimer Laser Annealing (ELA), Continuous Grain Silicon (CGS), Sequential Lateral Solidification (SLS) or Metal Induced Lateral Crystallization (MILC). Next, a first insulative layer 32, made of the material incapable of storing laser energy, is formed on the polysilicon layer 31. Material of the first insulative layer 32 includes silicon oxide, silicon nitride, a combination thereof, and the like. Then, a thin film 33 (such as an amorphous silicon film) is formed on the first insulative layer 32, as shown in FIG. 3A. Also, a thickness of the thin film 33 is equal to or less than about 50 Å, and preferably about 15˜25 Å.

Next, the thin film 33 is subjected under a laser annealing to form the numerous nano crystals 331 on the first insulative layer 32, as shown in FIG. 3B. A wavelength of the laser selected for laser annealing is equal to or less than about 500 nm, and preferably in the range of 200 nm to 500 nm. Also, the particle size average of nano crystals 331 could be less than about 10 nm. Afterward, a second insulative layer 35 is formed on the first insulative layer 32 to cover the nano crystals 331. Finally, a metal gate is formed on the second insulative layer 35, as shown in FIG. 3C. Also, the first insulative layer 32 and the second insulative layer 35 could be made of the same or different materials.

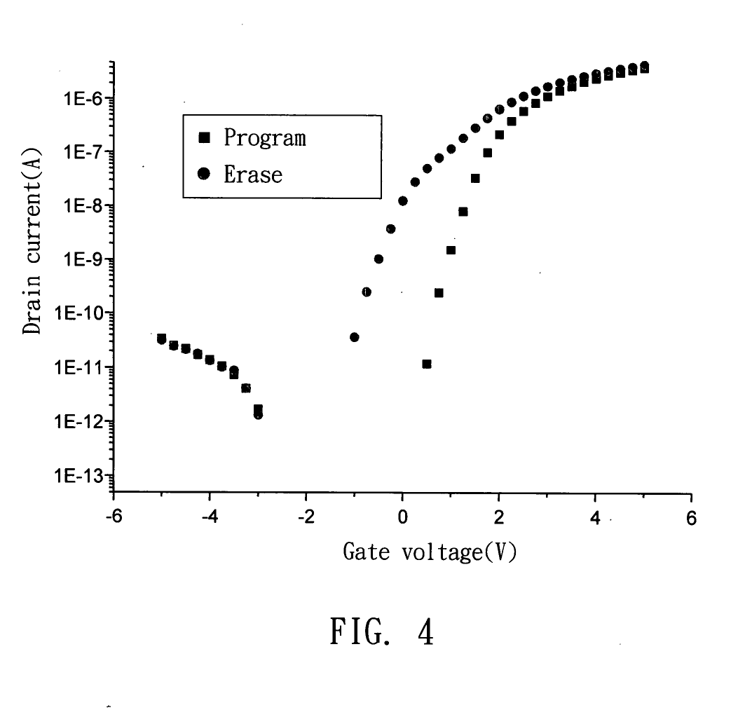

The nano crystals 331 of FIG. 3C function as the quantum wells of the memory device to trap the electrons. FIG. 4 is a graph showing the electrical property of the memory device having nano crystals manufactured according to the method of the present invention. The result of FIG. 4 indicated that the nano crystals do possess the function of quantum well.

Application 2: Solar Cell

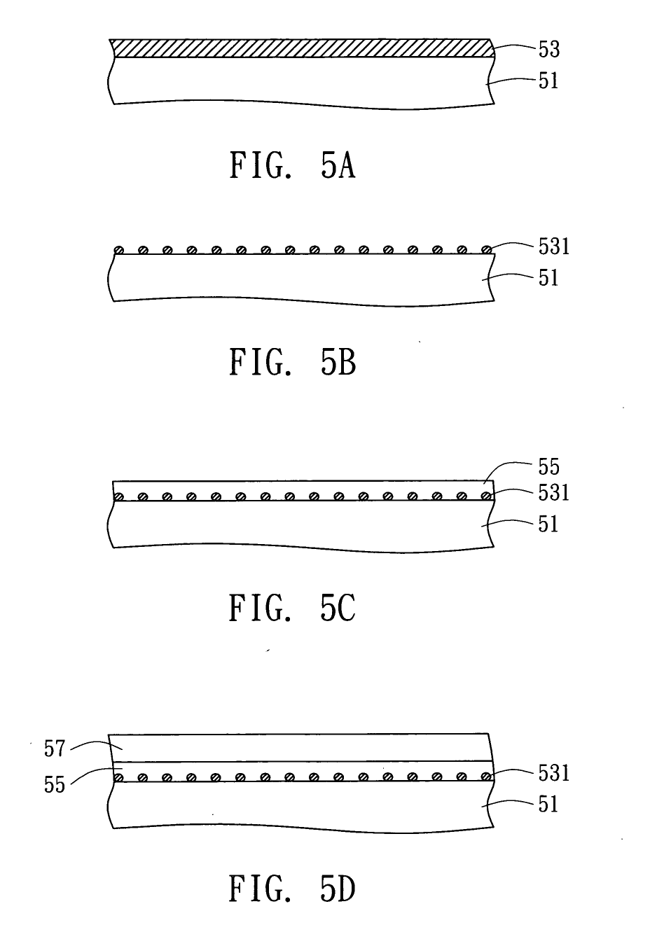

The nano crystals which possess good ability to store higher light energy can be applied to the fabrication of the solar cell. FIG. 5A˜5D are cross-sectional views showing a method of manufacturing the solar cell having nano crystals according to the embodiment of the present invention. First, a first metallic substrate 51 is provided, and a p-type silicon thin film 53 is formed on the first metallic substrate 51, as shown in FIG. 5A. A thickness of the p-type silicon thin film 53 is equal to or less than about 50 Å, and preferably about 15-25 Å. Then, the thin film 53 is subjected under a laser annealing to form the numerous p-type nano crystals 531 on the first metallic substrate 51, as shown in FIG. 5B. A wavelength of the laser selected for laser annealing is equal to or less than about 500 nm (preferably in the range of 200 nm to 500 nm). Next, an n-type silicon thin film 55 is formed on the first metallic substrate 51 to cover the nano crystals 531. Finally, a second metallic substrate 57 is formed on the n-type silicon thin film 55 to complete the fabrication of the solar cell, as shown in FIG. 5D.

When the solar cell is exposed to radiant energy, especially light, the positive-charged carriers are moved towards the p-type nano crystals 531, and the negative-charged carriers are moved towards the n-type silicon thin film 55; consequently, a voltage is produced. With an excellent ability of storing light energy of the nano crystals 531, the photoelectric characteristic of the solar cell is advanced.

While the invention has been described by way of example and in terms of the preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method of manufacturing nano crystals, comprising steps of:
providing a substrate;
forming a thin film on the substrate, and a thickness of the thin film equal to or less than about 50 Å; and
subjecting the thin film under a laser annealing to transform the thin film into a plurality of nano crystals, and a wavelength of the laser selected for laser annealing equal to or less than about 500 nm.

2. The method according to claim 1, wherein the substrate is a glass substrate.

3. The method according to claim 1, wherein the substrate is a plastic substrate.

4. The method according to claim 1, wherein the substrate is a metallic substrate.

5. The method according to claim 1, wherein the thickness of the thin film is in a range of about 15 Å to about 25 Å.

6. The method according to claim 1, wherein the thin film comprises silicon (Si), germanium (Ge) or SiGe.

7. The method according to claim 1, wherein the wavelength of the laser selected for laser annealing is in the range of about 200 nm to about 500 nm.

8. The method according to claim 1, wherein a particle size average of the nano crystals is less than about 10 nm.

9. The method according to claim 1, further comprising a step of forming an insulative layer on the substrate before the step of forming the thin film is performed.

10. The method according to claim 9, wherein the insulative layer comprises silicon oxide, silicon nitride, or a combination thereof.

11. A semiconductor structure having nano crystals, comprising:
a substrate;
a plurality of nano crystals formed on the substrate at a low crystallizing temperature, and a particle size average of the nano crystals is less than about 10 nm.

12. The semiconductor structure according to claim 11, wherein the substrate is a glass substrate.

13. The semiconductor structure according to claim 11, wherein the substrate is a plastic substrate.

14. The semiconductor structure according to claim 11, wherein the nano crystals are made of silicon (Si), germanium (Ge) or SiGe.

15. The semiconductor structure according to claim 11, further comprising an insulative layer formed on the substrate, and the nano crystals are formed on the insulative layer.

16. The semiconductor structure according to claim 15, wherein the insulative layer comprises silicon oxide, silicon nitride, or a combination thereof.

17. The semiconductor structure according to claim 11, wherein the nano crystals are formed on the substrate at a room temperature.
